(19) United States
(12) Patent Application Publication
(10) Pub. No.: US 2022/0225495 A1
(43) Pub. Date: Jul. 14, 2022

(54) CONTROL CIRCUIT BOARD

(71) Applicant: Wacom Co., Ltd., Saitama (JP)

(72) Inventor: Kohei HAYASHI, Saitama (JP)

(21) Appl. No.: 17/547,039

(22) Filed: Dec. 9, 2021

(30) Foreign Application Priority Data
Jan. 14, 2021 (CN) 202120101926.5

(51) Int. Cl. H05K 1/02; H05K 5/00; H05K 1/11

(52) U.S. Cl. CPC H05K 1/0268; H03K 17/962; H05K 1/114; H05K 5/0069

(57) ABSTRACT

There is provided a control circuit board including a board, an integrated circuit, and a pad group. The board includes a first surface and a second surface, where the first surface and the second surface are on opposite sides of the board. The integrated circuit is disposed on the first surface of the board. The pad group is disposed on the second surface of the board and is electrically connected to the integrated circuit through a through-hole formed in the board.

### BACKGROUND

### Technical Field

The present disclosure relates to a control circuit board.

### Description of the Related Art

In a control circuit board on which, for example, an integrated circuit is implemented, a pad group for testing is sometimes provided additionally on the board such that an operation test of the integrated circuit can be performed simply using an externally provided analysis apparatus.

FIG. 4 is a view exemplifying arrangement of pads on an existing control circuit board 1. The control circuit board 1 includes a board 2 and a plurality of electronic parts 3, 4, and 5 provided on a main surface of the board 2. A plurality of pads 6 are provided on the main surface of the board 2 in such a manner that they keep away from the positions of the plurality of electronic parts 3 to 5.

However, according to the control circuit board 1 depicted in FIG. 4, since the plurality of pads 6 are placed in a decentralized manner, man-hours for fixing connection terminals for external attachment to the individual pads 6 are required.

### BRIEF SUMMARY

According to an embodiment of the present disclosure, there is provided a control circuit board including a board including a first surface and a second surface, wherein the first surface and the second surface are on opposite sides of the board, an integrated circuit disposed on the first surface of the board, and a pad group disposed on the second surface of the board and electrically connected to the integrated circuit through a through-hole formed in the board.

Preferably, a protective film having insulation removably covers the pad group.

Preferably, the pad group includes a plurality of pads that extend in a first direction and are placed at equal distances along a second direction that is perpendicular to the first direction.

The integrated circuit may be a touch integrated circuit (IC) that has a communication interface for communicating with an external apparatus and that, in operation, may perform driving control of a touch sensor, and the pad group may be electrically connected to the communication interface through the through-hole formed in the board and enable the external apparatus to perform to perform an operation test of the touch IC through the communication interface.

With the present disclosure, an external attachment work of an analysis apparatus through a pad group to the control circuit board can be performed easily.

### BRIEF DESCRIPTION OF THE SEVERAL VIEWS OF THE DRAWINGS

FIG. 1 is a front elevational view of a control circuit board according to an embodiment of the present disclosure;

FIG. 2 is a partial enlarged view depicting a rear surface of the control circuit board of FIG. 1;

FIG. 3 is a view depicting a state in which a flat cable is connected to the control circuit board of FIG. 2; and

FIG. 4 is a view exemplifying arrangement of pads on an existing control circuit board.

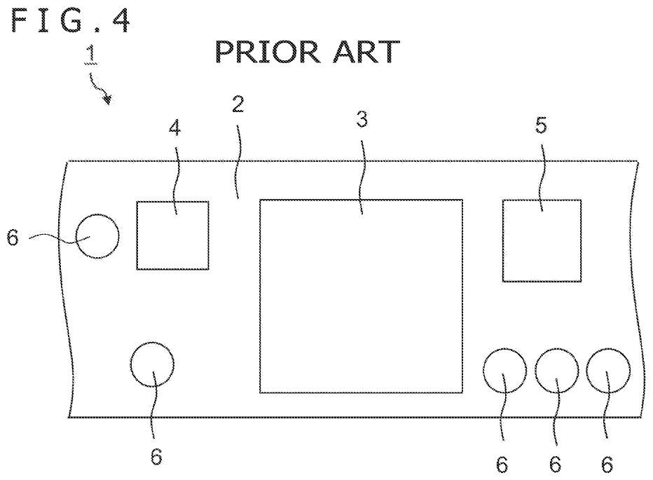

### DETAILED DESCRIPTION

In the following, an embodiment of the present disclosure is described with reference to the accompanying drawings. In order to facilitate understandings of the description, like components in the drawings are denoted by like reference signs as far as possible and overlapping description of them is omitted herein.

### Configuration

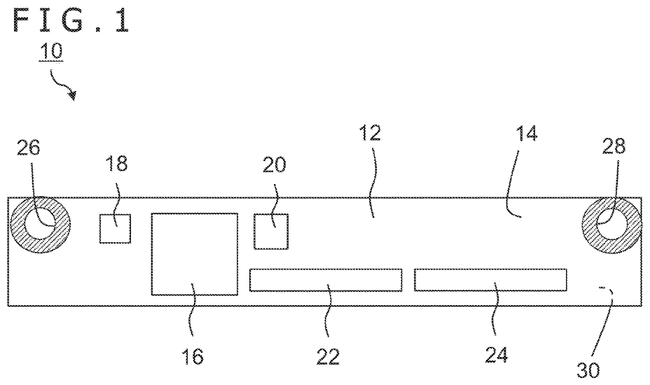

FIG. 1 is a front elevational view of a control circuit board 10 according to an embodiment of the present disclosure. Referring to FIG. 1, the control circuit board 10 is configured such that it is connected to a capacitive touch sensor not depicted to detect a position on a touch surface thereof pointed to by a finger of a user or a touch pen. It is to be noted that the control target is not limited to a touch sensor but may be any of sensors of various detection types, various electronic parts, and various kinds of electronic equipment.

The control circuit board 10 includes a board 12 of a substantially rectangular shape elongated in one direction. On one of two main surfaces of the board 12, an integrated circuit 16, electronic parts 18 and 20, and connectors 22 and 24 are provided. The main surface mentioned of the board 12 is hereinafter referred to as a “front surface 14.” The integrated circuit 16 is a touch IC that has a communication interface for communicating with an external apparatus and performs driving control of the touch sensor and synchronous control of the touch pen through execution of firmware. The connector 22 is configured for connection to an X-axis cable of the touch sensor. The connector 24 is configured for connection to a Y-axis cable of the touch sensor.

Through-holes 26 and 28 are formed at corner portions of the board 12. An inner wall of the board 12 surrounding each of the through-holes 26 and 28 is plated with copper. The integrated circuit 16 is connected to the through-holes 26 and 28 through printed wires not depicted. The through-holes 26 and 28 allow connection of the printed wires from the other main surface of the board 12 to the integrated circuit 16. The other main surface mentioned of the board 12 is hereinafter referred to as a “rear surface 30.”

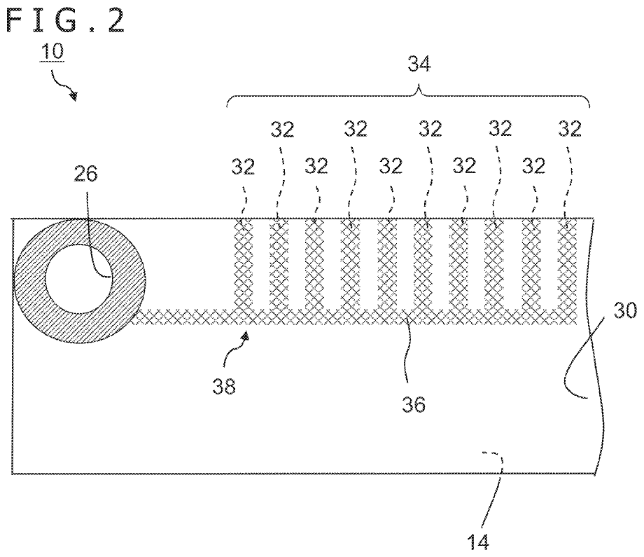

FIG. 2 is a partial enlarged view depicting the rear surface 30 of the control circuit board 10 of FIG. 1. On the rear surface 30 of the board 12, an aggregation of pads 32 and an aggregation of lead lines individually connected to one end of the pads 32 are provided. The aggregation of pads 32 and the aggregation of lead lines are hereinafter referred to as a pad group 34 and a lead line group 36, respectively.

The pad group 34 is used in order to perform an operation test of the integrated circuit 16 through the communication interface of the integrated circuit 16. The pad group 34 is placed densely at one place of the rear surface 30. The plurality of pads 32 configuring the pad group 34 extend in a short side direction of the board 12 and are placed at equal distances along a long side direction of the board 12.

Each of the lead lines configuring the lead line group 36 is connected at the other end thereof to the through-hole 26 described above. Consequently, the pad group 34 is electrically connected to the integrated circuit 16 through the through-hole 26. The pad group 34 and the lead line group 36 are covered from above with a protective film 38 having insulation. The protective film 38 can be removed by a physical process or a chemical process.

### Working Effect

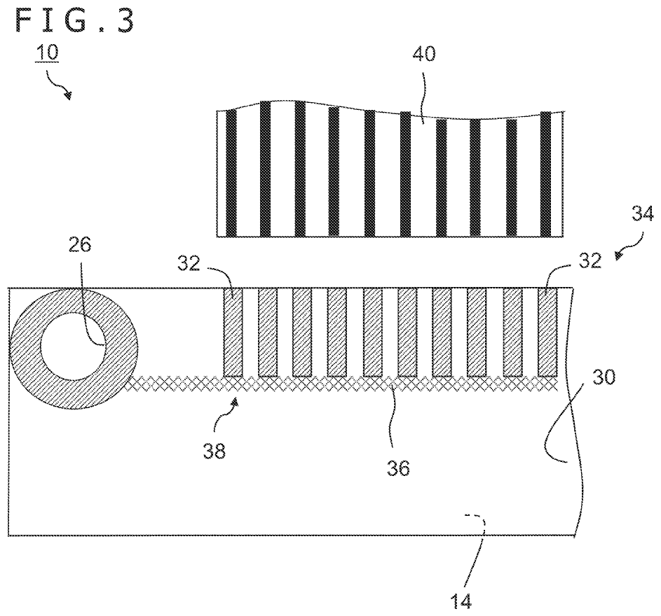

The control circuit board 10 according to the present embodiment is configured in such a manner as described above. Now, a working effect by the control circuit board 10 is described with reference to FIG. 3. The operation test described above may be performed at any of timings including (1) a timing of analysis of a product with which some problem is found after shipment, (2) another timing of operation checking before shipment of a product, and (3) a further timing of debugging in development of firmware.

FIG. 3 is a view depicting a state in which a flat cable 40 is connected to the control circuit board 10 of FIG. 2. The flat cable 40 is a flexible connection cable for connecting an analysis apparatus not depicted to the control circuit board 10. The flat cable 40 has, on the distal end side thereof, a connection terminal group in which connection terminals are placed at the same pitch as that of the pads 32.

A worker would first remove part of the protective film 38 provided on the rear surface 30 of the control circuit board 10 to expose the pad group 34 to the outside. Then, the worker would perform positioning of the flat cable 40 and then press the connection terminal group of the flat cable 40 against the pad group 34. Consequently, the connection terminal group of the flat cable 40 is fixed simultaneously and collectively to all of the pads 32 configuring the pad group 34, and therefore, they can be connected simply to the external analysis apparatus. Then, if the worker leads out the flat cable 40 to the outside of the electronic equipment while the control circuit board 10 is incorporated into the electronic equipment, then the worker can perform an operation test of the integrated circuit 16 in a state close to an actual operation environment of the electronic equipment.

It is to be noted that the specifications of the pad group 34, particularly the number, width, length, pitch, and so forth of the pads 32, may be common or different according to the model of the touch sensor, the touch pen, or the electronic equipment. Especially, if the specifications of the pad group 34 are made common, then the convenience upon testing is improved.

As described above, the control circuit board 10 includes a board 12, an integrated circuit 16 provided on a main surface 14 of the board 12, and a pad group 34 placed densely at one place of the rear surface 30 of the board 12 and electrically connected to the integrated circuit 16 through a through-hole 26 or 28 formed in the board 12.

Since the plurality of the pads 32 are placed densely at one place by using the rear surface 30 on which the integration density is relatively low in comparison with the front surface 14 on which the integrated circuit 16 is provided, it becomes easy to fix two or more pads 32 simultaneously and collectively to connection terminals for external attachment, in the example of FIG. 3, to the flat cable 40. Consequently, the external attachment work of an analysis apparatus through the pad group 34 is facilitated in comparison with that in an alternative case in which a plurality of pads 32 are placed in a decentralized manner at different locations.

Further, the pad group 34 may be covered in a removable state with a protective film 38 having insulation. The protective film 38 suppresses malfunction and so forth of the integrated circuit 16, which may possibly be caused by contact of the pad group 34 with a conductive part of the electronic equipment in which the control circuit board 10 is incorporated. Further, by removing the protective film 38 as occasion demands, the pad group 34 can be used timely.

Further, a plurality of pads 32 configuring the pad group 34 may extend in one direction (one side direction of the board 12) and be placed at equal distances along a direction perpendicular to the one direction (along the other side direction of the board 12). By the configuration, the control circuit board 10 can be connected simply to an external analysis apparatus through a flat cable 40 that has a connection terminal group in which connection terminals are placed at a pitch same as that of the pads 32.

The integrated circuit 16 may be a touch IC that has a communication interface for communicating with an external apparatus and performs driving control of a touch sensor, and the pad group 34 may be used to perform an operation test of the touch IC through the communication interface. This configuration makes it possible to easily perform an operation test of the touch sensor.

It is to be noted that the embodiment of the present disclosure is not limited to the foregoing embodiment, and that various changes can be made without departing from the spirit of the present disclosure.

What is claimed is:

1. A control circuit board comprising:
a board including a first surface and a second surface, wherein the first surface and the second surface are on opposite sides of the board;
an integrated circuit disposed on the first surface of the board; and
a pad group disposed on the second surface of the board and electrically connected to the integrated circuit through a through-hole formed in the board.

2. The control circuit board according to claim 1, wherein a protective film having electrical insulation removably covers the pad group.

3. The control circuit board according to claim 1, wherein the pad group includes a plurality of pads that extend in a first direction and are placed at equal distances along a second direction that is perpendicular to the first direction.

4. The control circuit board according to claim 3, further comprising:
a conductive metal disposed on an inner wall of the board surrounding the through hole; and
a plurality of lead lines disposed on the second surface of the board and electrically coupled to the conductive metal disposed on the inner wall of the board surrounding the through hole,
wherein an end of each of the plurality of pads is electrically connected to one of the plurality of lead lines.

5. The control circuit board according to claim 4, wherein the conductive metal is disposed on the first surface and the second surface of the board and extends on the first surface and the second surface of the board from the through hole to at least two outer edges of the board.

6. The control circuit board according to claim 1, wherein:
the integrated circuit is a touch integrated circuit that has a communication interface for communicating with an external apparatus,
the touch integrated circuit, in operation, performs driving control of a touch sensor, and
the pad group is electrically connected to the communication interface through the through-hole formed in the board and enables the external apparatus to perform an operation test of the touch integrated circuit through the communication interface.
